(19) United States
(12) Patent Application Publication
(10) Pub. No.: US 2016/0113161 A1
(43) Pub. Date: Apr. 21, 2016

(54) ELECTROMAGNETIC INTERFERENCE (EMI) SHIELDS INCLUDING SEE-THROUGH PORTIONS

(71) Applicant: Laird Technologies, Inc., Earth City, MO (US)

(72) Inventors: Shelby Ball, Frisco, TX (US); Larry D. Creasy, JR., St. Clair, MO (US)

(21) Appl. No.: 14/569,112

(22) Filed: Dec. 12, 2014

Related U.S. Application Data
(60) Provisional application No. 62/065,352, filed on Oct. 17, 2014.

(51) Int. Cl. H05K 9/00

(52) U.S. Cl. CPC H05K 9/0086; H05K 9/0032; H05K 9/0094

(57) ABSTRACT

According to various aspects, exemplary embodiments are disclosed of EMI shields that include see-through portions. In an exemplary embodiment, an EMI shielding apparatus or assembly generally includes a cover, lid, or top. The cover includes at least a portion that is see-through. Also disclosed are exemplary embodiments of methods relating to making EMI shielding apparatus or assemblies. Additionally, exemplary embodiments are disclosed of methods relating to providing shielding for one or more components on a substrate.

### CROSS-REFERENCE TO RELATED APPLICATION

This application claims the benefit of and priority to U.S. Provisional Application No. 62/065,352 filed Oct. 17, 2014. The entire disclosure of the above application is incorporated herein by reference.

### FIELD

The present disclosure generally relates to EMI shields that include see-through portions, such as covers, lids, or tops including see-through portions, etc.

### BACKGROUND

This section provides background information related to the present disclosure which is not necessarily prior art.

A common problem in the operation of electronic devices is the generation of electromagnetic radiation within the electronic circuitry of the equipment. Such radiation may result in electromagnetic interference (EMI) or radio frequency interference (RFI), which can interfere with the operation of other electronic devices within a certain proximity. Without adequate shielding, EMI/RFI interference may cause degradation or complete loss of important signals, thereby rendering the electronic equipment inefficient or inoperable.

A common solution to ameliorate the effects of EMI/RFI is through the use of shields capable of absorbing and/or reflecting and/or redirecting EMI energy. These shields are typically employed to localize EMI/RFI within its source, and to insulate other devices proximal to the EMI/RFI source.

The term “EMI” as used herein should be considered to generally include and refer to EMI emissions and RFI emissions, and the term “electromagnetic” should be considered to generally include and refer to electromagnetic and radio frequency from external sources and internal sources. Accordingly, the term shielding (as used herein) broadly includes and refers to mitigating (or limiting) EMI and/or RFI, such as by absorbing, reflecting, blocking, and/or redirecting the energy or some combination thereof so that it no longer interferes, for example, for government compliance and/or for internal functionality of the electronic component system.

### SUMMARY

This section provides a general summary of the disclosure, and is not a comprehensive disclosure of its full scope or all of its features.

According to various aspects, exemplary embodiments are disclosed of EMI shields that include see-through portions. In an exemplary embodiment, an EMI shielding apparatus or assembly generally includes a cover, lid, or top. The cover includes at least a portion that is see-through. Also disclosed are exemplary embodiments of methods relating to making EMI shielding apparatus or assemblies. Additionally, exemplary embodiments are disclosed of methods relating to providing shielding for one or more components on a substrate.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is an exploded perspective view of a shielding apparatus including a frame and a cover attachable to the frame, where the cover includes at least a portion that is see-through (e.g., transparent, semitransparent, substantially transparent, translucent, clear, etc.) according to an exemplary embodiment;

FIG. 2 is an exploded perspective view showing example layers that may be used for the cover shown in FIG. 1 including a first or top electrically-conductive layer or portion, a second or middle electrically-conductive adhesive layer or portion, and a third or bottom dielectric layer or portion according to an exemplary embodiment;

FIG. 3 provides example dimensions in millimeters (inches) that may be used for a cover in an exemplary embodiment;

FIGS. 4A, 4B, 4C, and 4D show example patterns of electrically-conductive material on film that may be used for a cover of a shielding apparatus according to an exemplary embodiment;

FIG. 5 is a perspective view of a see-through film that may be used for a cover of shielding apparatus according to an exemplary embodiment;

FIG. 6 is a perspective view of an example shielding apparatus including a frame and a cover attached to the frame, where the cover includes the see-through film shown in FIG. 5 according to an exemplary embodiment;

FIG. 7A is a top view of the shielding apparatus shown in FIG. 6, and showing how the cover allows viewing of the interior of the shielding apparatus through the cover according to an exemplary embodiment;

FIG. 7B is a close-up view of a portion of the shielding apparatus shown in FIG. 7A, and illustrating the metal mesh laminated to the underside of the film (e.g., polyester dielectric film, etc.) to thereby provide electrically conductivity along the underside of the film without entirely eliminating the ability to see through the film;

FIGS. 8A, 8B, 8C, and 8D are respective top, front, side, and cross-sectional views of an example frame of a shielding apparatus to which may be attached a cover having at least a portion that is see-through according to an exemplary embodiment, where the dimensions in millimeters (inches) are provided for purpose of example only; and

FIG. 9 is a line graph of shielding effectiveness in decibels (dB) versus frequency from 200 megahertz to 18 gigahertz measured for three prototype shielding apparatus including covers having portions that are see-through according to exemplary embodiments.

### DETAILED DESCRIPTION

Example embodiments will now be described more fully with reference to the accompanying drawings.

Board level shielding (BLS) may be used in electronic devices, such as smartphones, tablets, etc. Traditional BLS assemblies are commonly used, but they may include metal opaque covers that are not see-through. Because the covers are opaque and not see-through, the covers do not allow optical inspection or viewing of components within an interior of the shielding apparatus through the cover. Thus, the components are only able to be optically inspected or viewed (e.g., not visible to the human eye, etc.) if the cover is not on the frame, e.g., prior to attaching the cover to the frame or after the cover has been removed from the frame.

Disclosed herein are exemplary embodiments of EMI shields, shielding apparatus, or assemblies that include one or more portions (e.g., covers, lids, or tops, etc.) that are see-through (e.g., transparent, semitransparent, substantially transparent, translucent, clear, not opaque, etc.). In exemplary embodiments, an EMI shield, shielding apparatus or assembly generally includes a frame and a cover, lid, or top attachable or attached to the frame. The cover includes at least a portion that is at least partially see-through. An interior cooperatively defined by the frame and the cover may be optically inspected or viewed through the see-through portion of the cover. For example, components may be disposed within the interior of the shielding apparatus after the frame has been installed (e.g., soldered, etc.) to a PCB. The components within the interior may then be optically inspected or viewed (e.g., visible to the human eye, etc.) through the see-through portion of the cover without first having to remove the cover from the frame.

In another exemplary embodiment, an EMI shielding apparatus or assembly generally includes one or more sidewalls and a cover, lid, or top attachable or attached to the one or more sidewalls. The one or more sidewalls may comprise a single sidewall, may comprise a plurality of sidewalls that are separate or discrete from each other, or may comprise a plurality of sidewalls that are integral parts of a single-piece frame, etc. The cover includes at least a portion that is at least partially see-through (e.g., transparent, semitransparent, substantially transparent, translucent, clear, not opaque, etc.). An interior cooperatively defined by the sidewalls and the cover may be optically inspected or viewed through the see-through portion of the cover. For example, components may be disposed within the interior of the shielding apparatus after the sidewalls have been installed (e.g., soldered, etc.) to a PCB. The components within the interior may then be optically inspected or viewed through the see-through portion of the cover without first having to remove the cover from the sidewalls.

In exemplary embodiments, the cover, lid, or top includes multiple layers or portions such that the cover may also be referred to herein as a cover assembly. For example, the cover may include a first or top electrically-conductive layer or portion, a second electrically-conductive adhesive layer or portion, and a third or bottom dielectric layer or portion. The first or top layer may comprise a film, such as Mylar® polyester film, other polyester film, polyimide

(PI) film, polyethylene terephthalate (PET) film, polyethylene naphthalate (PEN) film, a high temperature polymer film, other film or material, etc. Electrically-conductive material may be disposed (e.g., printed in a grid or mesh pattern, etc.) on the film. For example, electrically-conductive (e.g., silver, etc.) ink or paste may be screen printed on the film. The second layer may comprise a pressure sensitive adhesive (PSA). The second layer may be annular with an open middle portion such that the adhesive is only along the perimeter edge portions of the first layer and does not obstruct the view through the first layer. The third or bottom layer may comprise a dielectric film (e.g., Mylar® dielectric polyester film, etc.) along or on an underside of the cover to inhibit shorting out components received under the cover. In some embodiments, the cover does not include the third dielectric layer such that the second layer is the bottom layer.

In some embodiments, a cover includes one or more see-through portions that have an optical transparency or light transmission of 70% or more (e.g., 70%, 80%, 90%, greater than 80%, etc.). The optical transparency or light transmission will depend on the particular materials used for the cover.

The cover may have a perimeter or footprint that is sized and shaped to match or correspond to a size and shape of the frame's perimeter or footprint. In some embodiments, the footprint or perimeter of the cover may be smaller than the footprint or perimeter of the frame so that the cover does not extend beyond or overhand any edges of the frame. The frame may include one or more sidewalls defining an open top of the frame. The cover may be attached along or to the upper surface of the frame so as to cover the open top of the frame. The shielding apparatus may be operable for shielding one or more components on a substrate when the one or more components are within an interior cooperatively defined by the frame and the cover attached to the frame.

The sidewalls may be integrally formed, such that the sidewalls have a single-piece or unitary construction. In which case, the frame would not include any gaps between adjacent pairs of the sidewalls that allow EMI leakage. The frame also would not include any joints connecting separate sidewalls to each other as the frame's sidewalls would be integrally connected to each other. Alternatively, the EMI shielding apparatus may include sidewalls comprised of multiple separate pieces instead of a frame.

The cover, lid, or top may be applied to a frame or sidewalls using adhesive (e.g., an electrically-conductive PSA, etc.). The cover may have substantially the same shape as the frame so that the cover will cover substantially all of a perimeter or open top defined by the frame. For example, the cover may be applied to a first side of the frame to form a surface covering the open top of the frame and an interior defined by the frame. The interior defined by the frame may be substantially hollow, and may be covered by the cover such that the frame and cover may cooperatively provide shielding for components received within the interior cooperatively defined by the frame and cover. The cover may be see-through, thereby allowing viewing of the components received within the interior cooperatively defined by the frame and cover, without having to remove the cover.

In some embodiments, the cover may include an electrical insulator or dielectric as a bottom layer of the cover. The dielectric layer may be coupled to the first layer (e.g., electrically-conductive see-through layer, etc.) and/or to the second layer (e.g., pressure sensitive layer, etc.). The electrical insulator or dielectric may provide electrical insulation to inhibit the cover from electrically shorting any components received under the cover within the interior cooperatively defined by the frame and cover. The electrical insulator or dielectric layer may comprise Mylar® dielectric polyester film, other dielectric polyester film, dielectric polyimide (PI) film, dielectric polyethylene naphthalate (PEN) film, other dielectric film or material, etc. The electrical insulator or dielectric layer may also be see-through (e.g., transparent, semitransparent, substantially transparent, translucent, clear, not opaque, etc.) so that the dielectric layer does not obstruct the view through the cover.

The cover may be attached to a first side of the frame, e.g., using an electrically-conductive PSA, etc. An electrically-conductive PSA may be applied or coupled to a second side of the frame opposite the first side to which the cover is attached. The electrically-conductive PSA may be used to install the frame to a circuit board such that the shielding assembly provides board level shielding for one or more components of the circuit board. In other exemplary embodiments, the frame may be solderable to (e.g., soldering pads along or on, etc.) a substrate.

In some exemplary embodiments, the cover may be less than about one millimeter (mm) tall, and may allow for optical inspection or viewing of components received under the cover within the interior of the cover and frame after installation on a circuit board or other substrate. The cover may include one or more materials (e.g., polyimide (PI), other high temperature polymer, etc.) suitable for withstanding (e.g., without significant deformation or shrinkage, etc.) the reflow soldering process used to install the frame to a PCB. This may eliminate the need for secondary installation as the frame and cover may be assembled together and then installed to the PCB as an assembled complete unit. For example, the cover may first be attached to the frame before the frame is installed (e.g., soldered, etc.) to a PCB. Then, the frame with the cover attached thereto may be applied as a complete unit for reflow, thus eliminating the secondary post-installation step of attaching the cover to the frame after the frame has been installed to the PCB. In exemplary embodiments, the cover comprises a high temperature resistant film (e.g., dielectric polyethylene terephthalate (PET) film, dielectric polyimide (PIM) film, etc.) having electrically-conductive material (e.g., electrically-conductive ink or paste, etc.) thereon, where the cover is able to withstand solder reflow (e.g., withstand reflow temperatures of 250 degrees Celsius and a cycle time of nine minutes, etc.).

The cover may include an electrically-conductive see-through film or layer, which may be attached to the frame with an adhesive (e.g., electrically-conductive pressure-sensitive adhesive, etc.). The cover may also include an electrical insulator (e.g., dielectric layer along or on an underside of the cover, etc.) to inhibit shorting out components received in the interior of the frame and cover in some embodiments. In other embodiments, the cover may not include any such electrical insulator. Some exemplary embodiments may reduce tooling cost when compared to a conventional two-piece metal BLS shield.

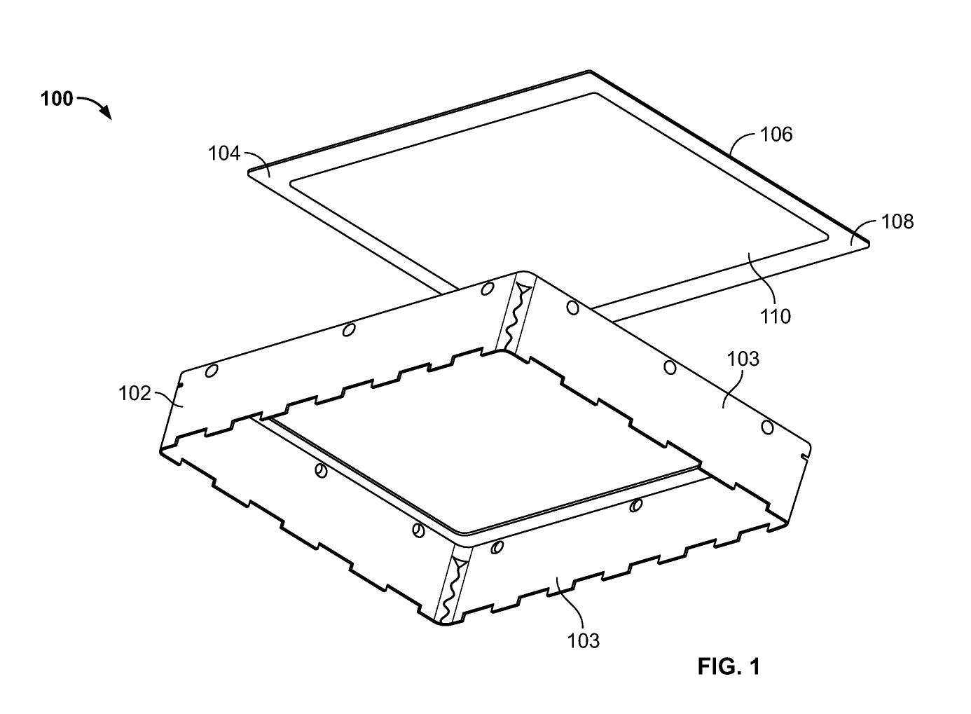

With reference to the figures, FIG. 1 illustrates an exemplary embodiment of a shielding apparatus or assembly 100 according to aspects of the present disclosure. The assembly 100 includes a frame 102 and a cover, lid, or top 104.

As disclosed herein, the cover 104 includes at least a portion that is see-through (e.g., transparent, semitransparent, substantially transparent, translucent, clear, not opaque, etc.). The see-through portion of the cover 104 allows an interior cooperatively defined by the frame 102 and the cover 104 to be optically inspected or viewed through the see-through portion of the cover 104 without having to remove the cover 104 from the frame 102. For example, components may be disposed within the interior of the shielding apparatus 100 after the frame 102 has been installed (e.g., soldered, etc.) to a PCB. The components within the interior may then be optically inspected or viewed through the see-through portion of the cover 104 without first having to remove the cover 104 from the frame 102.

The frame 102 comprises an electrically-conductive EMI shielding material, such as metal (e.g., cold rolled steel, sheet metal, etc.), etc. The frame 102 includes sidewalls 103 that define an open top of the frame 102. The cover 104 is attachable (e.g., via electrically-conductive PSA, etc.) to upper or top surfaces of the sidewalls 103 such that the open top of the frame 102 is covered by the cover 104. For example, electrically-conductive PSA may be positioned between and along the upper surfaces of the sidewalls 103 and the perimeter edge portions of the cover 104. In this example, the bottom surfaces of the sidewalls 103 are configured to be soldered to corresponding solder pads on a PCB. Alternatively, electrically-conductive PSA may be along the bottom surfaces of the sidewalls 103 for attaching the frame 102 to a substrate, e.g., PCB, etc. By way of example only, the electrically-conductive PSA may be electrically-conductive PSA tape from Laird Technologies, such as LT-301 PSA tape having a thickness of about 0.09 millimeters, a peel strength on stainless steel of greater than 1.3 kilogram force per 25 millimeters, and Z-axis resistance of less than 0.05 ohms. Alternatively, the cover may be attachable to the frame via other means and/or the frame may be attachable to a substrate via other means.

The cover 104 comprises an EMI shielding surface in the form of an electrically-conductive see-through film. The cover 104 may also include one or more other layers or portions, such that the cover 104 may also be referred to herein as a cover assembly. For example, FIG. 3 illustrates example layers or portions 106, 108, 110 that may be used for the cover 104 shown in FIG. 1. As shown in FIG. 3, the cover 104 includes a first or top electrically-conductive layer or portion 106, a second or middle electrically-conductive adhesive layer or portion 108, and a third or bottom dielectric layer or portion 110.

The first layer 106 may comprise a see-through film, substrate, or layer having electrically-conductive material thereon such that the first layer 106 remains at least partially see-through despite the presence of the electrically-conductive material. For example, the electrically-conductive material is not coated or applied over the entire surface of the film. Instead, the electrically-conductive material is only on or along a portion of the film, e.g., in grid or mesh pattern, striped pattern, wave cross patterns, diamond pattern, etc. In other embodiments, a film may include electrically-conductive particles therein. For example, a film may be filled with or have suspended therein electrically-conductive particles. In still other exemplary embodiments, a cover may include an electrically-conductive (e.g., metal, etc.) mesh without any film backing. In such embodiments, the mesh may have sufficient strength and rigidity such that it may be used as a standalone cover that is attached (e.g., adhesively attached via an electrically-conductive pressure sensitive adhesive (CPSA), etc.) around a perimeter of the frame. The mesh may be configured so that it is see through and has good shielding effectiveness.

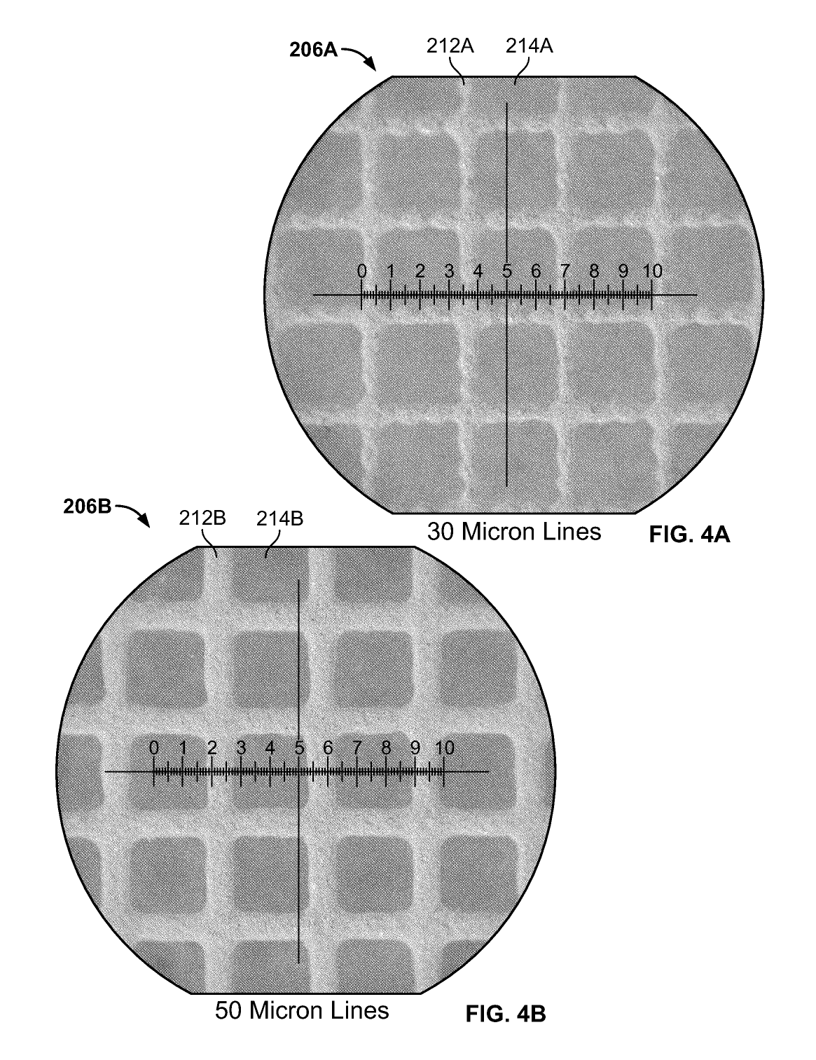

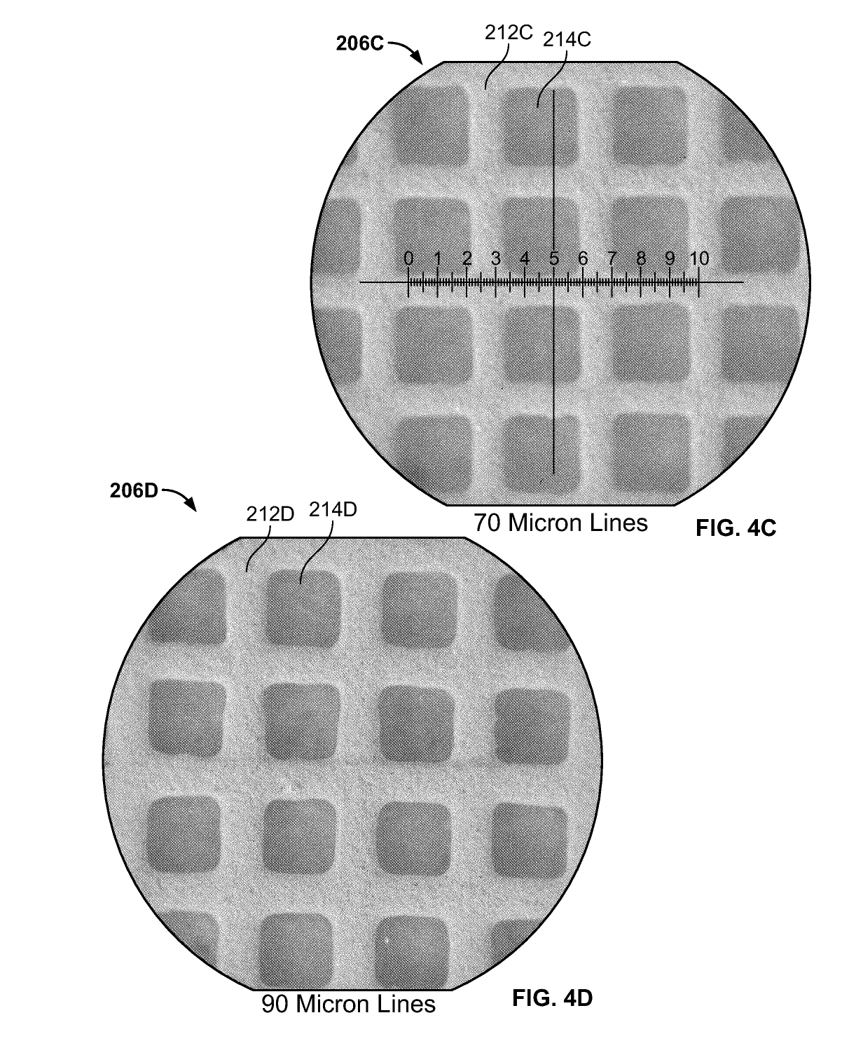

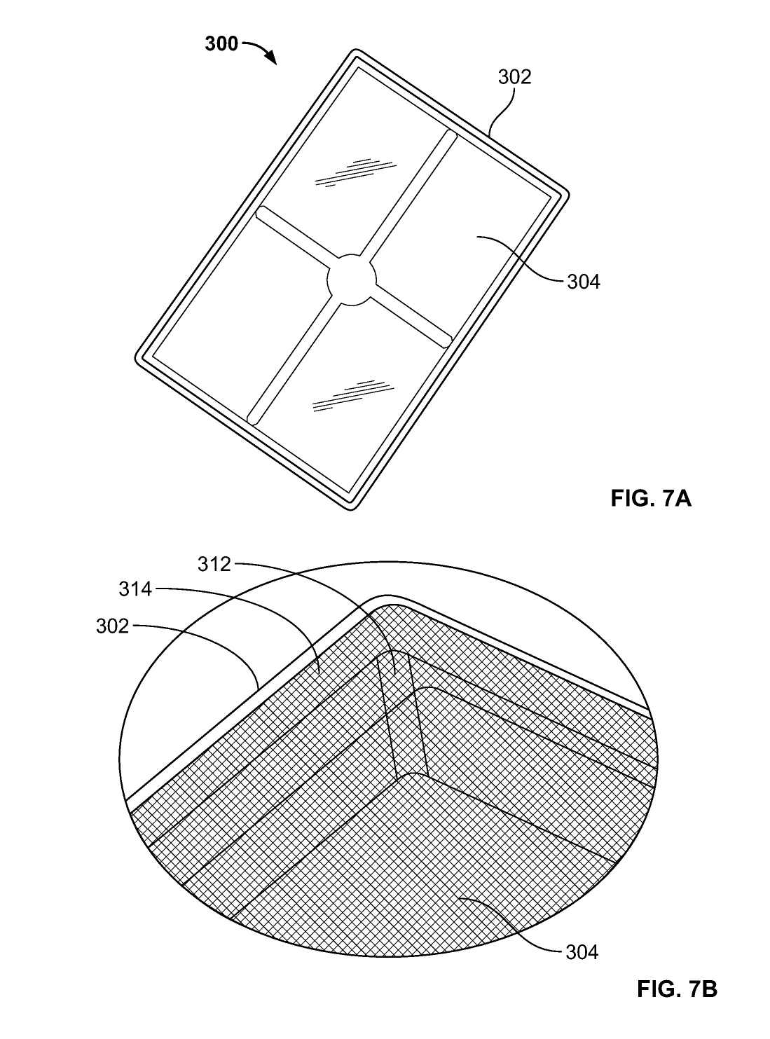

The film may comprise Mylar® polyester film, other polyester film, polyimide (PI) film, polyethylene terephthalate (PET) film, polyethylene naphthalate (PEN) film, other films, other materials, etc. The electrically-conductive material may comprise electrically-conductive ink or paste (e.g., silver ink or paste, etc.) applied (e.g., printed, etc.) onto either or both surfaces of the film. In exemplary embodiments, silver ink or paste is screen printed in a grid or mesh pattern (e.g., FIGS. 4A through 4D, FIG. 7B, etc.) onto the bottom surface of a see-through yellow translucent polyimide (PI) film. Other embodiments may include different electrically-conductive materials and/or that are applied differently than screen printing and/or to different films.

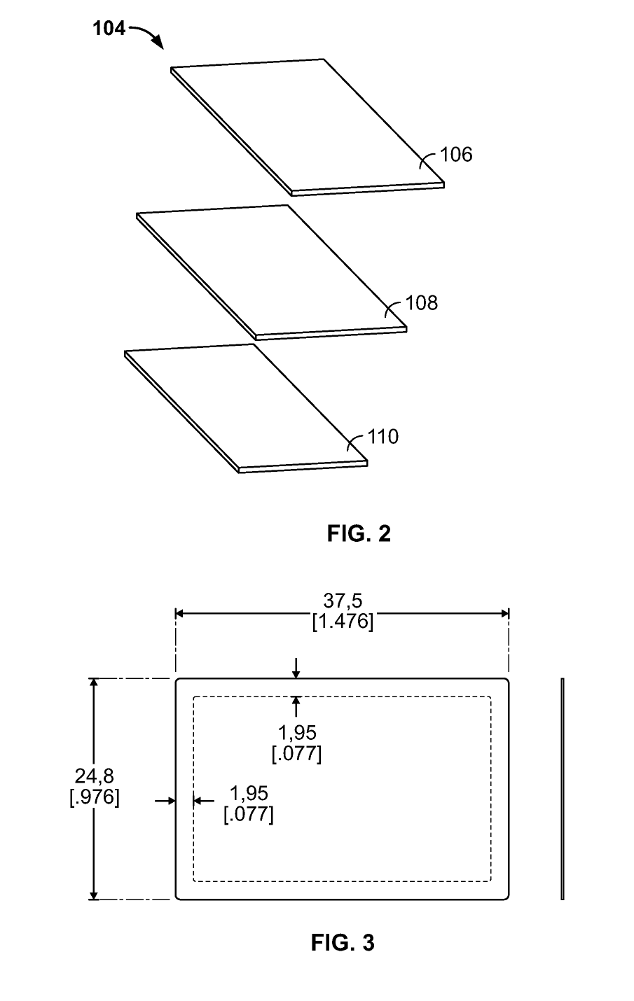

The second layer 108 may comprise an electrically-conductive PSA. The second layer 108 may be see-through (e.g., transparent, translucent, not opaque, etc.) and comprise a layer as shown in FIG. 2 that is not annular. Alternatively, the second layer 108 may be annular with an open middle portion. In which case, the PSA may be disposed only along only the perimeter edge portions of the first layer 106 such that the PSA does not obstruct the view through the first layer 106. By way of example only, the second layer 108 may comprise electrically-conductive PSA tape from Laird Technologies, such as LT-301 PSA tape having a thickness of about 0.09 millimeters, a peel strength on stainless steel of greater than 1.3 kilogram force per 25 millimeters, and Z-axis resistance of less than 0.05 ohms.

The third layer 110 may comprise a dielectric or electrical insulator along or on an underside of the cover 104. The third layer 110 may provide electrical insulation to inhibit the cover 104 from electrically shorting any components received under the cover 104 within the interior cooperatively defined by the frame 102 and cover 104. In some embodiments, the cover 104 does not include any such dielectric or electrical insulator.

The third layer 110 may be coupled to the first layer 106 (e.g., electrically-conductive see-through layer, etc.) and/or to the second layer 108 (e.g., pressure sensitive layer, etc.). The third layer 110 may comprise Mylar® dielectric polyester film, other dielectric polyester film, dielectric polyimide (PI) film, dielectric polyethylene naphthalate (PEN) film, other dielectric films, other materials, etc. The third layer 110 may be see-through and not opaque so that the third layer 110 does not obstruct optical inspection or viewing of components, etc. through the cover 104.

In this example, the electrically-conductive see-through film 106 is on the top. The electrically-conductive PSA 108 is in the middle. And, the electrical insulator or dielectric 110 is on bottom. In other embodiments, the cover 104 may have a different configuration or arrangement of layers and/or more or less than three layers.

Although FIG. 1 illustrates the frame 102 and cover 104 having rectangular shapes, other exemplary embodiments may include frames and covers having different configurations (e.g., circular, triangular, irregular, other non-rectangular shapes, etc.). In this illustrated embodiment, the shielding apparatus 100 is free of interior walls, dividers, or partitions such that the sidewalls 103 of the frame 102 generally define a single interior space or compartment. In other exemplary embodiments, a frame may include one or more interior walls, dividers, or partitions (e.g., extending between and/or attached to sidewalls of the frame, etc.) for sectioning the frame into two or more interior spaces.

FIG. 3 provides example dimensions in millimeters (inches) that may be used for the cover 104 or a cover in other exemplary embodiments. The cover 104 may be sized according to the size of the frame 102. For example, the cover 104 may be sized to have a footprint or perimeter large enough to cover the open top of the frame 102 but smaller than the footprint or perimeter of the frame 102. This, in turn, may help prevent any portions of the cover 104 from extending beyond or overhanging the outside edges of the frame 102 and contacting or sticking to unwanted adjacent components. The cover 104 may have any suitable thickness or height, including less than about 1 mm, etc. The dimensions provided in this paragraph and FIG. 2 are examples only as other embodiments may include a differently configured cover that is larger, smaller, or shaped differently.

FIGS. 4A through 4D shows respective patterns of electrically-conductive material 212A, 212B, 212C, 212D on see-through films 214A, 214B, 214C, 214D that may be used as a layer 206A, 206B, 206C, 206D of a multi-layer cover assembly (e.g., cover 104, etc.). Or, for example, the dielectric film 214A, 214B, 214C, 214D having the electrically-conductive material 212A, 212B, 212C, 212D thereon may be used as the cover by itself without any additional layers.

As shown in FIGS. 4A through 4D, the electrically-conductive material 212 is provided along the film 214 in a grid or mesh pattern. The grid or mesh pattern is configured (e.g., line width, mesh size, spacing/pitch, etc.) so that the layer 206 remains see-through despite the presence of the electrically-conductive material 212. For example, the electrically-conductive material 212 is not applied (e.g., screen printed, etc.) over the entire surface of the film 214. Instead, portions of the film 214 are not provided with the electrically-conductive material 212 so that those portions remain see-through.

In these illustrated examples of FIGS. 4A through 4D, the electrically-conductive material 212 comprises silver ink or paste that is screen printed onto a see-through yellow translucent dielectric polyimide (PI) film. The line width of the silver is 30 microns in FIG. 4A. The line width of the silver is 50 microns in FIG. 4B. The line width of the silver is 70 microns in FIG. 4C. The line width of the silver is 90 microns in FIG. 4D. The mesh spacing may be about 250 microns or micrometers. Other embodiments may include electrically-conductive material in a different configuration, e.g., line width greater than 90 microns, less than 30 microns, within a range from 30 to 90 microns (e.g., 40 micrometers, 60 micrometers, 80 micrometers, etc.), different mesh or grid pattern (e.g., closer or greater spacing than 250 micrometers, smaller or larger mesh size, etc.), etc. In addition, other films may be used instead of PI film (e.g., other high temperature polymer films, etc.) and/or other electrically-conductive materials may be used instead of silver, such as copper, stainless steel, aluminum, or other electrically-conductive material, etc. Other processes may also be used for applying an electrically-conductive material to a film instead of screen printing, such as spraying, screen printing, sputtering (also known as Plasma Vapor Deposition or PVD), etching, coating, lamination of metal wire mesh with or without a film material backing, etc.

A wide variety of meshes (e.g., materials, opening sizes, open areas, wire diameters, etc.) may be used in exemplary embodiments of the present disclosure. The following are examples of meshes that may be used in exemplary embodiments:
silver-plated stainless steel mesh having 50 openings per inch, wire diameter of 0.0012 inches, and 88.4% open area;
silver-plated stainless steel mesh having 80 openings per inch, wire diameter of 0.0011 inches, and 82% open area;
silver-plated stainless steel mesh having 100 openings per inch, wire diameter of 0.0011 inches, and 79.2% open area;
copper mesh having 100 openings per inch, wire diameter of 0.0022 inches, and 60.8% open area;
copper mesh having 80 openings per inch, wire diameter of 0.0005 inches, and 86% open area; and/or
stainless steel mesh having 230 openings per inch, wire diameter of 0.0014 inches, and 46% open area.

With continued reference to FIGS. 4A through 4D, the electrically-conductive grid pattern, line width, and distance between lines is selectively determined in order to provide a balance between having good shielding effectiveness and retaining the ability to see through the film. For example, if the grid pattern lines are too close together and/or too thick, the shielding effectiveness may be exceptional. But it may then not be possible to see through the film due to the grid lines, e.g., the grid lines may prevent optical inspection and/or viewing of components as the portions of the film that do not include the grid lines may be too small, etc.

In some embodiments, the film may have a high shrink resistance to reduce shrinking in high heat environments, such as during solder reflow, etc. For example, the film preferably is able to withstand the solder reflow processes commonly used to install a frame to a circuit board.

FIG. 5 illustrates an example cover, lid, or top 304 for a shielding apparatus according to an exemplary embodiment. As shown in FIG. 5, the cover 304 comprise a substantially transparent or clear film.

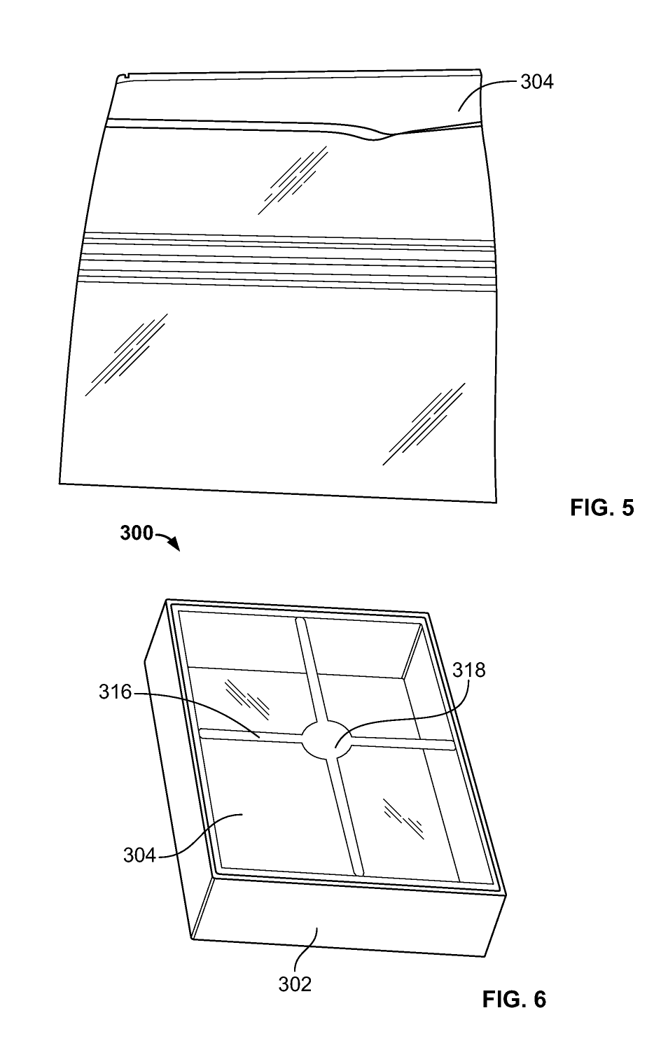

FIG. 6 illustrates an exemplary shielding apparatus or assembly 300 that includes a frame 302 and the cover 304 shown in FIG. 5. The cover 304 is coupled to a top side of the frame 302. The frame 302 includes an open top that is covered by the cover 304. In this example, the shielding apparatus or assembly 300 may be referred to as a two-piece shield, shielding apparatus or assembly with one piece being the frame 302 and the other piece being the cover 304.

The cover 304 may be attached to the frame 302, e.g., using an adhesive (e.g., electrically-conductive PSA, etc.) or other suitable means. The frame 302 may be installed or mounted to a PCB using solder, etc. Alternatively, an adhesive may be provided along the bottom side of the frame 302, which adhesive is used for installing or mounting the shielding apparatus 300 to a substrate (e.g., printed circuit board, etc.).

The cover 304 may initially be larger than a perimeter or footprint of the frame 302. If so, the cover 304 may be cut or otherwise reduced down in size to correspond to the size of the perimeter or footprint of the frame 302. In some embodiments, the cover 304 may be sized to have a footprint or perimeter large enough to cover the open top of the frame 302 but smaller than the footprint or perimeter of the frame 302. This, in turn, may help prevent any portions of the cover 304 from extending beyond or overhanging the outside edges of the frame 302 and contacting or sticking to unwanted adjacent components. For example, the frame 302 may have sidewalls that bend across the top edge. The cover 304 might be cut slightly smaller than the perimeter of the frame 302 to prevent any pressure-sensitive adhesive along the cover 304 from hanging over the edge of the frame 302 and sticking to unwanted components.

As shown in FIG. 6, the frame 302 includes crossbars 316, which may provide additional support for the frame 302, extra shielding for the shielding assembly 300, support a pickup surface 318 for pick-n-place equipment, etc. In other embodiments, the frame does not include any crossbars 316. For example, the frame 102 shown in FIG. 1 does not include any crossbars. This may improve optical inspection and/or viewing of components through the cover 104 as there are no frame crossbars to obstruct the view through the cover 104, thus allowing for better inspection and/or viewing through the cover 104.

FIG. 7A is a top view of the shielding apparatus or assembly 300 of FIG. 6. As shown in FIG. 7A, it is possible to see through the cover 304 into the interior of the assembly 300 without removing the cover 304.

FIG. 7B is a close-up view of a portion of the shielding apparatus 300 shown in FIG. 7A. As shown in FIG. 7B, a metal mesh 312 is laminated to the underside of the film 314 (e.g., polyester dielectric film, high temperature polymer film, etc.) to thereby provide electrically conductivity along the underside of the film 314 without entirely eliminating the ability to see through the film 314. Accordingly, the cover 304 includes at least a portion that is see-through (e.g., transparent, semitransparent, substantially transparent, translucent, clear, etc.).

The film 314 may comprise a Mylar® polyester film, other polyester film, polyimide (PI) film, polyethylene terephthalate (PET) film, polyethylene naphthalate (PEN) film, a high temperature polymer film, other film or material, etc. In exemplary embodiments, the film 314 comprises one or more materials (e.g., polyimide (PI), other high temperature polymer, etc.) suitable for withstanding (e.g., without significant deformation or shrinkage, etc.) the reflow soldering process used to install the frame to a PCB. The film 314 may comprise a dielectric film to which the metal mesh 312 provides electrical conductivity along the film's underside after being laminated to the underside of the dielectric film. The metal mesh 312 has a large enough opening size to allow the film to be see through, but the metal mesh's opening size is also small enough to achieve good shielding effectiveness. The mesh may be modified to improve shielding effectiveness (e.g., by reducing the opening size) or to improve transparency (e.g., by increasing the opening size).

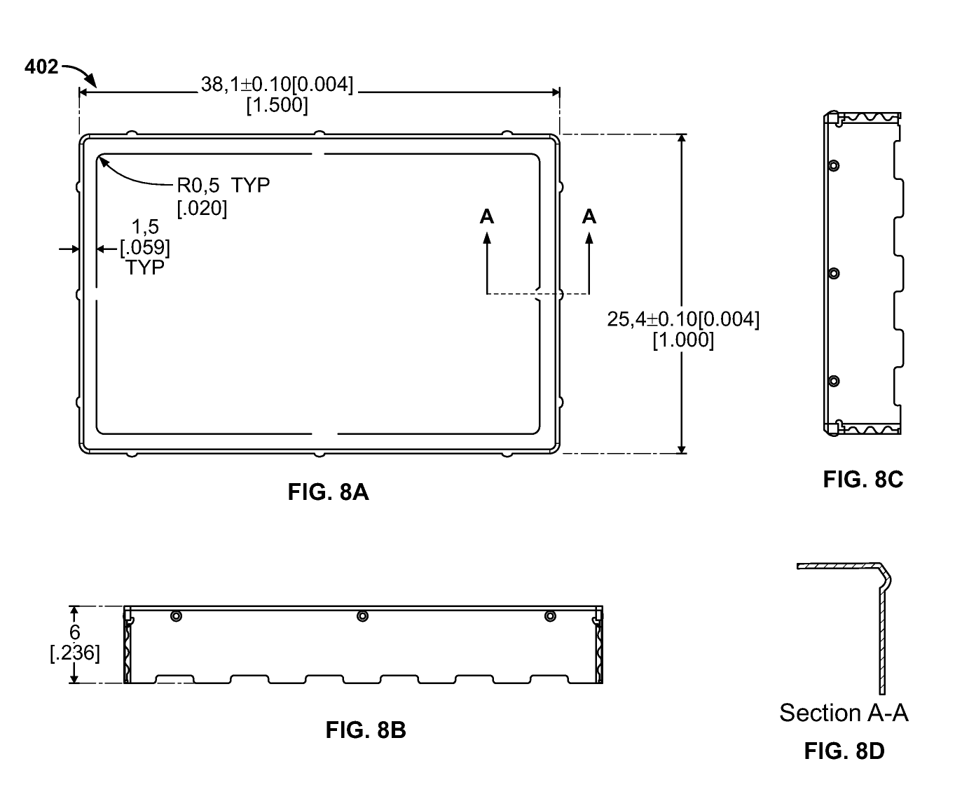

FIGS. 8A, 8B, 8C, and 8D are respective top, front, side, and cross-sectional views of an example frame 402 to which may be attached a cover having at least a portion that is see-through according to an exemplary embodiment. The example dimensions in millimeters (inches) provided in these figures (and elsewhere in this patent application) are examples only as other embodiments may include a differently configured frame that is larger, smaller, or shaped differently.

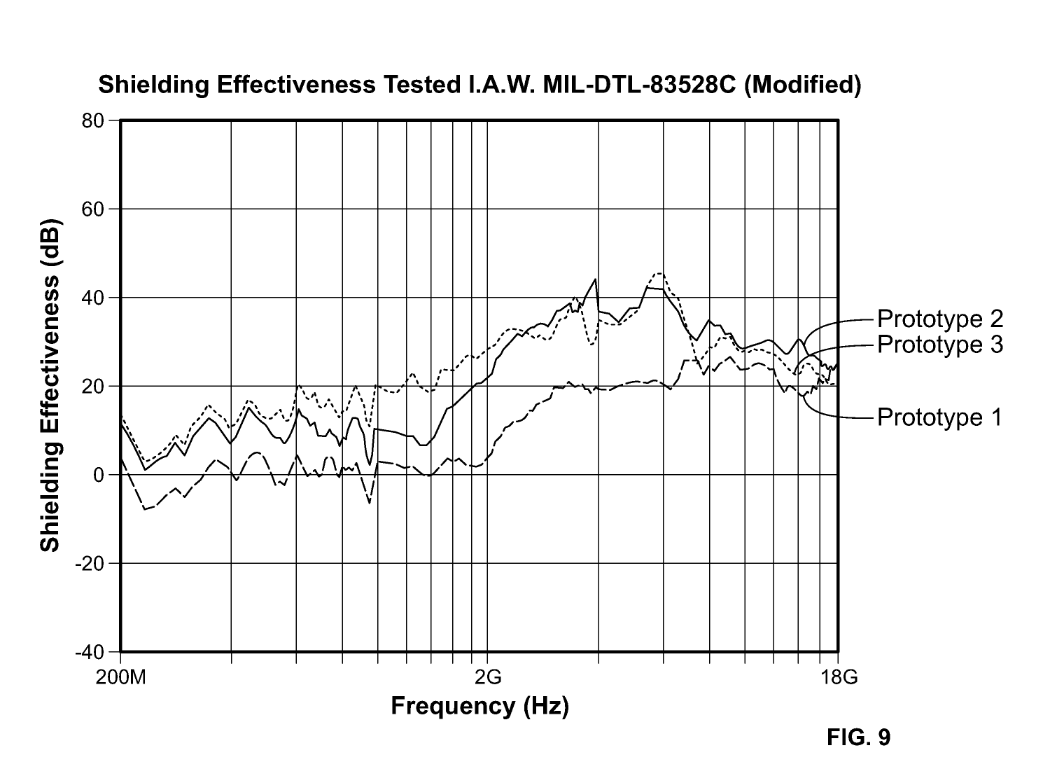

FIG. 9 is a line graph of shielding effectiveness in decibels (dB) versus frequency from 200 megahertz to 18 gigahertz measured for three prototype shielding apparatus each including covers including see-through portions according to exemplary embodiments of the present disclosure. The results shown in FIG. 9 are provided only for purposes of illustration and not for purposes of limitation as other exemplary embodiments of shielding apparatus may be configured differently such that they have different shielding effectiveness (e.g., better than 20 dB to 40 dB shielding effectiveness, etc.). The three prototype shielding apparatus included frames made of cold rolled steel, where the frames included crossbars (e.g., FIGS. 5 and 6, etc.). But crossbars are not required as other embodiments included frames without any crossbars (e.g., FIGS. 1 and 8A, etc.). The first prototype (Prototype 1) included an optical grade polyethylene terephthalate (PET) film coated with an electrically-conductive transparent coating thereon. The second prototype (Prototype 2) included a transparent plastic film having an electrically-conductive grid thereon in a diamond pattern. The third prototype (Prototype 3) included a clear polyethylene terephthalate (PET) film sputter coated with a multi-layer electrically-conductive coating. Generally, these results showed that good shielding effectiveness (e.g., 20 dB to 40 dB, greater than 40 dB, etc.) across a range of frequencies may be obtained with an EMI shielding apparatus that includes a cover having at least a portion that is see through as disclosed herein.

Other exemplary embodiments include methods of making board level EMI shielding apparatus or assemblies. In an exemplary embodiment, a method generally includes covering an open top defined by one or more sidewalls with a cover having at least one see-through portion that is at least partially see-through (e.g., transparent, translucent, not opaque, etc.). The one or more sidewalls are configured for installation to a substrate generally about one or more components on the substrate. The one or more sidewalls and the cover are operable for shielding the one or more components on the substrate when the one or more components are within an interior cooperatively defined by the one or more sidewalls and the cover. The see-through portion of the cover allows for optical inspectional and/or viewing of the one or more components through the cover's see-through portion without having to remove the cover.

This exemplary method may include using an electrically-conductive pressure sensitive adhesive to attach the cover to the one or more sidewalls. The method may include soldering the one or more sidewalls to the circuit board while the cover is attached to the one or more sidewalls. The method may also include optically inspecting and/or viewing the one or more components through the see-through portion of the cover without removing the cover. The one or more sidewalls may comprise a single sidewall, may comprise a plurality of sidewalls that are separate or discrete from each other, or may comprise a plurality of sidewalls that are integral parts of a single-piece frame, etc.

Further exemplary embodiments include methods relating to providing shielding for one or more components on a substrate. In an exemplary embodiment, a method generally includes attaching a cover to one or more sidewalls, and attaching the one or more sidewalls to the substrate such that the one or more components are disposed within an interior cooperatively defined by the cover and the one or more sidewalls. The cover includes at least one see-through portion that is at least partially see-through (e.g., transparent, translucent, not opaque, etc.). The one or more sidewalls may comprise a single sidewall, may comprise a plurality of sidewalls that are separate or discrete from each other, or may comprise a plurality of sidewalls that are integral parts of a single-piece frame, etc.

In some exemplary embodiments, a frame may include one or more outer sidewalls and one or more interior walls, dividers, or partitions. The sidewalls and interior walls of the frame may be defined by electrically-conductive shielding material. The cover and the frame's sidewalls and interior walls may cooperatively define a plurality of individual EMI shielding compartments. When the frame is installed (e.g., adhesively attached, soldered to soldering pads, etc.) to a substrate (e.g., printed circuit board, etc.), components on the substrate may be positioned in different compartments such that the components are provided with EMI shielding by virtue of the EMI shielding compartments inhibiting the ingress and/or egress of EMI into and/or out of each EMI shielding compartment. In other exemplary embodiments, the frame may not include or may be free of interior walls, dividers, or partitions such that the sidewalls of the frame generally define a single interior space or compartment.

In some exemplary embodiments, a frame may include one or more sidewalls defined by electrically-conductive foam or other electrically-conductive porous material. In such exemplary embodiments, the electrically-conductive foam or porous material may undergo a flame retardant treatment. For example, the internal surfaces of the foam or porous material may be provided with an effective amount of a flame retardant. In the context of the present disclosure, an “effective amount” may be considered as an amount of the flame retardant that provides the foam or porous material with at least horizontal flame rating of UL94 V-0, V-1, V-2, HB, or HF-1, while at the same time retaining a Z-axis conductivity or bulk resistivity sufficient for EMI shielding applications. The amount of the flame retardant dispersed may be about 10 ounces per square yard (opsy) or less, about 5 opsy or less, about 3 opsy, etc. By way of example only, the flame retardant treatment may be similar or identical to a flame retardant coating process described in U.S. Pat. No. 7,060,348 and/or U.S. Patent Application Publication 2014/0199904 by which the electrically-conductive shielding material may be UL94 V-0 and halogen free. The entire disclosures of U.S. Pat. No. 7,060,348 and U.S. Patent Application Publication 2014/0199904 are incorporated herein by reference.

In some exemplary embodiments, at least a portion (e.g., a frame, a lid or cover, etc.) of the shielding apparatus or assembly may be thermally conductive to help establish or define at least a portion of a thermally-conductive heat path from a heat source (e.g., board-mounted heat generating electronic component of an electronic device, etc.) to a heat dissipating and/or heat removal structure, such as a heat sink, an exterior case or housing of an electronic device (e.g., cellular phone, smart phone, tablet, laptop, personal computer, etc.), heat spreader, heat pipe, etc. For example, a frame and/or cover may be electrically conductive and thermally conductive. In this example, one or more thermal interface materials (e.g., compliant or conformable thermal interface pad, putty, or gap filler, etc.) may be disposed along (e.g., adhesively attached via a PSA tape, etc.) an inner and/or outer surface of the frame and/or cover. For example, a thermal interface material may be disposed along an outer surface of the cover or lid after the EMI shielding apparatus has been installed to a PCB and the components under the cover have been optically inspected or viewed through the cover. The thermal interface material may be configured to make contact (e.g., direct physical contact, etc.) with a heat dissipating device or heat removal structure. By way of further example, the thermal interface material may comprise a conformable and/or flowable thermal interface material having sufficient compressibility, flexibility, deformability, and/or flowability to allow the thermal interface material to relatively closely conform to the size and outer shape of the heat dissipating device or heat removal structure, thereby removing air gaps therebetween. The thermal interface may also be a form-in-place material such that it can be dispensed in place onto the shielding apparatus.

In embodiments that include one or more thermal interface materials, a wide variety of materials may be used for any of the one or more thermal interface materials (TIMs) in those exemplary embodiments. For example, the one or more TIMs may be formed from materials that are better thermal conductors and have higher thermal conductivities than air alone. The one or more TIMs may comprise thermal interface materials from Laird Technologies, such as Tflex™ 300 series thermal gap filler materials, Tflex™ 600 series thermal gap filler materials, Tpcm™ 580 series phase change materials, Tpcm™ 780 series phase change materials Tpli™ 200 series gap fillers, and/or Tgrease™ 880 series thermal greases, etc. By way of further example, a TIM may be molded from thermally-conductive and electrically-conductive elastomer. A TIM may comprise a thermally-conductive compliant material or thermally conductive interface material formed from ceramic particles, metal particles, ferrite EMI/RFI absorbing particles, metal or fiberglass meshes in a base of rubber, gel, grease or wax, etc. Exemplary embodiments may include a TIM with a thermal conductivity higher than 6 W/mK, less than 1.2 W/mK, or other values between 1.2 and 6 W/mk. For example, a TIM may be used that has a thermal conductivity higher than air's thermal conductivity of 0.024 W/mK, such as a thermal conductivity of about 0.3 W/mk, of about 3.0 W/mK, or somewhere between 0.3 W/mk and 3.0 W/mk, etc.

A TIM may include compliant or conformable silicone pads, non-silicone based materials (e.g., non-silicone based gap filler materials, thermoplastic and/or thermoset polymeric, elastomeric materials, etc.), silk screened materials, polyurethane foams or gels, thermal putties, thermal greases, thermally-conductive additives, etc. A TIM may be configured to have sufficient conformability, compliability, and/or softness to allow the TIM material to closely conform to a mating surface when placed in contact with the mating surface, including a non-flat, curved, or uneven mating surface. A TIM may comprise an electrically conductive soft thermal interface material formed from elastomer and at least one thermally-conductive metal, boron nitride, and/or ceramic filler, such that the soft thermal interface material is conformable even without undergoing a phase change or reflow. The TIM may be a non-metal, non-phase change material that does not include metal and that is conformable even without undergoing a phase change or reflow. A TIM may comprise a thermal interface phase change material.

A TIM may comprise one or more conformable thermal interface material gap filler pads having sufficient deformability, compliance, conformability, compressibility, flowability, and/or flexibility for allowing a pad to relatively closely conform (e.g., in a relatively close fitting and encapsulating manner, etc.) to the size and outer shape of another component. Also, the thermal interface material gap filler pad may be a non-phase change material and/or be configured to adjust for tolerance or gap by deflecting.

In some exemplary embodiments, the thermal interface material may comprise a non-phase change gap filler, gap pad, or putty that is conformable without having to melt or undergo a phase change. The thermal interface material may be able to adjust for tolerance or gaps by deflecting at low temperatures (e.g., room temperature of 20° C. to 25° C., etc.). The thermal interface material may have a Young's modulus and Hardness Shore value considerably lower than copper or aluminum. The thermal interface material may also have a greater percent deflection versus pressure than copper or aluminum.

In some exemplary embodiments, the thermal interface material comprises T-flex™ 300 ceramic filled silicone elastomer gap filler or T-flex™ 600 boron nitride filled silicone elastomer gap filler, which both have a Young's modulus of about 0.000689 gigapascals. Accordingly, exemplary embodiments may include thermal interface materials having a Young's module much less than 1 gigapascal. T-flex™ 300 ceramic filled silicone elastomer gap filler and T-flex™ 600 boron nitride filled silicone elastomer gap filler have a Shore 00 hardness value (per the ASTMD2240 test method) of about 27 and 25, respectively. In some other exemplary embodiments, the thermal interface material may comprise T-pli™ 200 boron nitride filled, silicone elastomer, fiberglass reinforced gap filler having a Shore 00 hardness of about 70 or 75. Accordingly, exemplary embodiments may include thermal interface materials having a Shore 00 hardness less than 100. T-flex™ 300 series thermal gap filler materials generally include, e.g., ceramic, filled silicone elastomer which will deflect to over 50% at pressures of 50 pounds per square inch and other properties shown below. T-flex™ 600 series thermal gap filler materials generally include boron nitride filled silicone elastomer, which recover to over 90% of their original thickness after compression under low pressure (e.g., 10 to 100 pounds per square inch, etc.), have a hardness of 25 Shore 00 or 40 Shore 00 per ASTM D2240. Tpli™ 200 series gap fillers generally include reinforced boron nitride filled silicone elastomer, have a hardness of 75 Shore 00 or 70 Shore 00 per ASTM D2240. Tpcm™ 580 series phase change materials are generally non-reinforced films having a phase change softening temperature of about 122 degrees Fahrenheit (50 degrees Celsius). Tgrease™ 880 series thermal grease is generally a silicone-based thermal grease having a viscosity of less than 1,500,000 centipoises. Other exemplary embodiments may include a TIM with a hardness of less 25 Shore 00, greater than 75 Shore 00, between 25 and 75 Shore 00, etc.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms, and that neither should be construed to limit the scope of the disclosure. In some example embodiments, well-known processes, well-known device structures, and well-known technologies are not described in detail. In addition, advantages and improvements that may be achieved with one or more exemplary embodiments of the present disclosure are provided for purpose of illustration only and do not limit the scope of the present disclosure, as exemplary embodiments disclosed herein may provide all or none of the above mentioned advantages and improvements and still fall within the scope of the present disclosure.

Specific dimensions, specific materials, and/or specific shapes disclosed herein are example in nature and do not limit the scope of the present disclosure. The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter (i.e., the disclosure of a first value and a second value for a given parameter can be interpreted as disclosing that any value between the first and second values could also be employed for the given parameter). For example, if Parameter X is exemplified herein to have value A and also exemplified to have value Z, it is envisioned that parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, and 3-9.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “aving,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The term “about” when applied to values indicates that the calculation or the measurement allows some slight imprecision in the value (with some approach to exactness in the value; approximately or reasonably close to the value; nearly). If, for some reason, the imprecision provided by “about” is not otherwise understood in the art with this ordinary meaning, then “about” as used herein indicates at least variations that may arise from ordinary methods of measuring or using such parameters. For example, the terms “generally”, “about”, and “substantially” may be used herein to mean within manufacturing tolerances. For example, the tolerances may be +/−0.1 mm for dimensions from 0.5 mm to 6 mm, +/−0.2 mm for dimensions from 6 mm to 30 mm, +/−0.3 mm for dimensions from 30 mm to 120 mm, +/−0.5 mm for dimensions from 120 mm to 400 mm, +/−0.1 mm for holes, and/or an angular tolerance of +/−1 degree, etc.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements, intended or stated uses, or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A board level shielding apparatus comprising:
one or more sidewalls defining an open top and configured for installation to a substrate generally about one or more components on the substrate; and
a cover attachable to the one or more sidewalls for covering the open top, the cover including at least one see-through portion;
whereby the shielding apparatus is operable for providing board level shielding for one or more components on a substrate when the one or more components are within an interior cooperatively defined by the one or more sidewalls and the cover is attached to the one or more sidewalls, and whereby the see-through portion of the cover allows the one or more components to be optically inspected and/or viewed through the see-through portion without having to remove the cover from the one or more sidewalls.

2. The shielding apparatus of claim 1, wherein the cover comprises a first electrically-conductive layer that includes a see-through film having electrically-conductive material thereon, a second electrically-conductive adhesive layer, and a third dielectric layer along an underside of the cover to inhibit shorting out components received under the cover within the interior cooperatively defined by the one or more sidewalls and the cover.

3. The shielding apparatus of claim 2, wherein the see-through portion of the cover comprises one or more portions of the see-through film without any electrically-conductive material thereon, and wherein:
the second electrically-conductive adhesive layer is see-through; or
the second electrically-conductive adhesive layer is annular with an open middle portion such that second electrically-conductive adhesive layer is along only perimeter edge portions of the first electrically-conductive layer and does not obstruct the view through the first electrically-conductive layer.

4. The shielding apparatus of claim 1, wherein the cover comprises a transparent or translucent film having electrically-conductive material screen printed thereon.

5. The shielding apparatus of claim 4, wherein the electrically-conductive material comprises silver ink or silver paste screen printed onto the transparent or translucent film and having a line width greater than 30 microns.

6. The shielding apparatus of claim 5, wherein the silver ink or silver paste defines a mesh or grid pattern on the transparent or translucent film having a mesh spacing of about 250 microns.

7. The shielding apparatus of claim 6, wherein the transparent or translucent film comprises a see-through yellow translucent dielectric polyimide film able to withstand solder reflow temperatures of 250 degrees Celsius and a cycle time of nine minutes.

8. The shielding apparatus of claim 1, wherein the cover comprises a transparent or translucent film having electrically-conductive material thereon in a grid or mesh pattern having a line width greater than 30 microns and/or a mesh spacing of about 250 microns.

9. The shielding apparatus of claim 1, wherein the cover comprises a translucent dielectric polyimide or polyethylene terephthalate film having electrically-conductive material screen printed thereon and that is able to withstand a solder reflow process.

10. The shielding apparatus of claim 1, wherein the cover comprises an electrically-conductive mesh that comprises:
silver-plated stainless steel mesh having 50 openings per inch, wire diameter of 0.0012 inches, and/or 88.4% open area; or
silver-plated stainless steel mesh having 80 openings per inch, wire diameter of 0.0011 inches, and/or 82% open area; or
silver-plated stainless steel mesh having 100 openings per inch, wire diameter of 0.0011 inches, and/or 79.2% open area; or
copper mesh having 100 openings per inch, wire diameter of 0.0022 inches, and/or 60.8% open area; or
copper mesh having 80 openings per inch, wire diameter of 0.0005 inches, and/or 86% open area; or
stainless steel mesh having 230 openings per inch, wire diameter of 0.0014 inches, and/or 46% open area.

11. The shielding apparatus of claim 1, wherein the cover consists of an electrically-conductive mesh without any film material backing such that the electrically-conductive mesh is usable as a standalone cover when adhesively attached to the one or more sidewalls.

12. The shielding apparatus of claim 1, wherein:
the shielding apparatus comprises a frame that includes the one or more sidewalls;
the cover is adhesively attached to the frame;
the one or more components are visible through the see-through portion of the cover when the frame is on the substrate with the one or more sidewalls disposed about the one or more components on the substrate; and
a perimeter of the cover is less than a perimeter of the frame such that the cover does not extends outwardly beyond the perimeter of the frame when the cover is attached to the frame.

13. A cover for a board level shielding apparatus for use in providing board level EMI shielding for one or more components on a substrate, the cover configured for covering an open top of the shielding apparatus, the cover including at least one see-through portion, whereby the see-through portion of the cover allows an interior defined by the shielding apparatus and components within the interior to be optically inspected and/or viewed through the see-through portion without having to remove the cover.

14. The cover of claim 13, wherein the cover comprises a first electrically-conductive layer that includes a transparent or translucent film having electrically-conductive material thereon, and wherein the see-through portion of the cover comprises one or more portions of the transparent or translucent film without any electrically-conductive material thereon, and wherein the cover further comprises:
a second electrically-conductive adhesive layer that is see-through or anular with an open middle portion such that the second electrically-conductive adhesive layer is along only perimeter edge portions of the first electrically-conductive layer and does not obstruct the view through the first electrically-conductive layer; and
a third dielectric layer along an underside of the cover to inhibit shorting out components received under the cover within the interior cooperatively defined by the one or more sidewalls and the cover.

15. The cover of claim 13, wherein:
the cover comprises a transparent or translucent film and silver ink or silver paste screen printed in a mesh or grid pattern onto the transparent or translucent film with a line width greater than 30 microns and/or a mesh spacing of about 250 microns; or
the cover consists of an electrically-conductive mesh without any film material backing such that the electrically-conductive mesh is usable as a standalone cover.

16. A board level shielding apparatus comprising the cover of claim 13 and a frame including one or more sidewalls defining an open top and configured for installation to the substrate generally about the one or more components on the substrate, wherein the cover is adhesively attached to the frame over the open top, wherein the cover comprises a polyimide or polyethylene terephthalate film able to withstand a solder reflow process such that the frame is solderable to the substrate, whereby the shielding apparatus is operable for providing board level shielding for the one or more components on the substrate when the one or more components are within an interior cooperatively defined by the frame and the cover, and whereby the see-through portion of the cover allows the one or more components to be optically inspected and/or viewed through the see-through portion without having to remove the cover from the one or more sidewalls.

17. A method of making the board level shielding apparatus of claim 1, comprising covering the open top defined by the one or more sidewalls with the cover having the at least one see-through portion.

18. (canceled)

19. A method relating to providing shielding for one or more components on a substrate using the board level shielding apparatus of claim 1, the method comprising:
attaching the cover to the one or more sidewalls over the open top defined by the one or more sidewalls; and
attaching the one or more sidewalls to the substrate such that the one or more components are disposed within an interior cooperatively defined by the one or more sidewalls and the cover, whereby the see-through portion of the cover allows the one or more components to be optically inspected and/or viewed through the see-through portion disposed over the open top without having to remove the cover from the one or more sidewalls.

20. (canceled)

21. The shielding apparatus of claim 1, wherein the cover comprises:
an optical grade polyethylene terephthalate film coated with an electrically-conductive transparent coating thereon; or
a transparent plastic film having an electrically-conductive grid thereon in a diamond pattern; or
a clear polyethylene terephthalate film sputter coated with a multi-layer electrically-conductive coating.

22. An electronic device comprising the board level shielding apparatus of claim 1 a printed circuit board having one or more components on the printed circuit board, wherein:
the board level shielding apparatus comprises a frame that includes the one or more sidewalls;
an electrically-conductive pressure sensitive adhesive that adhesively attaches the cover to a first side of the frame;
a second side of the frame is adhesively attached or soldered to the printed circuit board;
the board level shielding apparatus is operable for providing board level shielding for the one or more components on the printed circuit board within the interior cooperatively defined by the one or more sidewalls and the cover, and whereby the see-through portion of the cover allows the one or more components to be optically inspected and/or viewed through the see-through portion without having to remove the cover from the frame.
